(19) United States
(12) Patent Application Publication
(10) Pub. No.: US 2015/0369856 A1
(43) Pub. Date: Dec. 24, 2015

(54) OVERVOLTAGE PROTECTION ELEMENT MONITORING

(71) Applicant: ABBY OY, Helsinki (FI)

(72) Inventors: Marko Takala, Vaasa (FI); Tero Kentala, Vaasa (FI); Harri Mattlar, Iskmo (FI); Matti Kähkipuro, Hyvinkää (FI); Tommi Rantalen, Ylöjärvi (FI)

(21) Appl. No.: 14/758,473

(22) PCT Filed: Dec. 28, 2012
(86) PCT No.: PCT/FI2012/051308

§ 371 Date: Jun. 29, 2015

(51) Int. Cl. G01R 31/28; H01C 7/12; H02H 3/20

(52) U.S. Cl. CPC G01R 31/2827; H02H 3/20; H01C 7/12

(57) ABSTRACT

The invention relates to a method and an arrangement for determining an end-of-life of an overvoltage protection element (2) by determining (101) a predefined voltage limit based on a nominal voltage, determining (102) a measuring voltage across switch components (5) of the switch arrangement in connection with a switch-off event, and determining (103) that the overvoltage protection element (2) has reached its end-of-life when the measuring voltage is equal to or lower than the predefined voltage limit.

### BACKGROUND

The present invention relates to a method and an arrangement for switching electric circuits. More specifically, the method and the arrangement relate to monitoring an end-of-life of an overvoltage protection element.

Overvoltage protection elements, such as varistors, are used in electric circuits to shunt an unusually high voltage away from more sensitive components.

One of the problems associated with varistors is that they have a limited lifetime and their leakage current increases over time due to the wear of the varistor. On the other hand, there are standards limiting the highest allowed leakage current values for different switch types.

### BRIEF DESCRIPTION

An object of the present solution is thus to provide a new method and an arrangement for implementing the method. The objects of the invention are achieved by a method and an arrangement, which are characterized by what is stated in the independent claims. The preferred embodiments of the invention are disclosed in the dependent claims.

The solution is based on the idea that aging of an overvoltage protection element can be monitored based on a measuring voltage of the overvoltage protection element and/or current through the overvoltage protection element.

An advantageous feature of the method and arrangement of the solution is that it is possible to detect an overvoltage protection element heading the end of its lifetime early enough before its leakage current increases to such a high value that a switch arrangement cannot switch off current anymore and that the leakage current limits provided in standards can no longer be fulfilled.

### BRIEF DESCRIPTION OF THE DRAWINGS

In the following the solution will be described in greater detail by means of preferred embodiments with reference to the attached [accompanying] drawings, in which

FIG. 1 describes schematically a method for determining an end-of-life of an overvoltage protection element;

FIG. 2 is a schematic view of an arrangement for determining an end-of-fife of an overvoltage protection element; and

FIG. 3 is a schematic view of an example of a switch arrangement for determining an end-of-life of a overvoltage protection element.

### DETAILED DESCRIPTION

Overvoltage is a voltage that exceeds a designed maximum supply voltage of one or multiple components of an electric circuit and may cause substantial damage to the component(s). An overvoltage may occur in connection with switching inductive loads off, for example. The quicker the current is switched off, the bigger the overvoltage problem tends to be. Thus, to protect the sensitive components, use of overvoltage protection element(s) is often necessary. Such an overvoltage protection element may comprise a varistor, such as a metal oxide varistor (MOV). The overvoltage protection should be connected parallel to the electric circuit and/or a component to be protected such that it absorbs the inductive energy of the main circuit.

Such overvoltage protection elements comprising a varistor have a lifetime that is dependent of the amount of energy absorbed in the overvoltage protection element. The bigger the transients are, the shorter the overall lifetime of the overvoltage protection element will be. When an overvoltage protection element, such as a varistor, absorbs energy, the junctions of the overvoltage protection element start to degrade. This degradation results in the voltage measured across the overvoltage protection element while it is in conductive state to lower from the original and intended nominal voltage to a lower voltage value. This actual measured voltage value across a conductive overvoltage protection element is called measuring voltage in this description and it is the voltage value at which the overvoltage protection element, thus, actually forms a low resistance shunt across its terminals.

In other words, the overvoltage protection element is in conductive state if the voltage across the overvoltage protection element tends to exceed the measuring voltage and the overvoltage protection element conducts as much current as it takes to keep the voltage across the overvoltage protection element at the measuring voltage. When the voltage across the overvoltage protection element decreases to a value lower than the measuring value, the current flow through the overvoltage protection element stops. The most typical problem with varistor-type overvoltage protection elements occurs when the measuring value decreases to a value lower than the peak value of the voltage of the system. When this occurs, the overvoltage protection element is continuously in conductive state and, thus, any switches connected in parallel with it cannot switch off the current in the electric circuit. At the same time, the continuous current flow through the overvoltage protection element accelerates the wear of the overvoltage protection element that may, in the end, cause a short circuit.

According to an embodiment, the end-of-life of the overvoltage protection element may be specified to be reached once the measuring voltage of the overvoltage protection element has been changed, for instance, by approximately 10 percent of the nominal voltage, which is the original and intended measuring voltage of the overvoltage protection element. According to another embodiment, the end-of-life of the overvoltage protection element may be specified to be reached once the measuring voltage is substantially equal to the peak value of the voltage of the system. It is important to detect the end-of-life of the overvoltage protection element and/or the approaching of the end-of-life as early or quickly as possible, as a weakened element may not function as intended and, thus, fulfil its purpose.

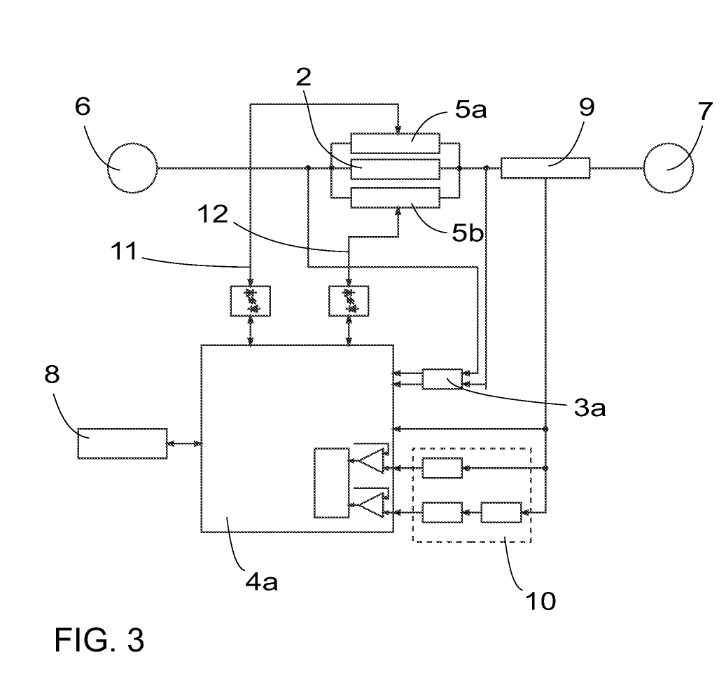

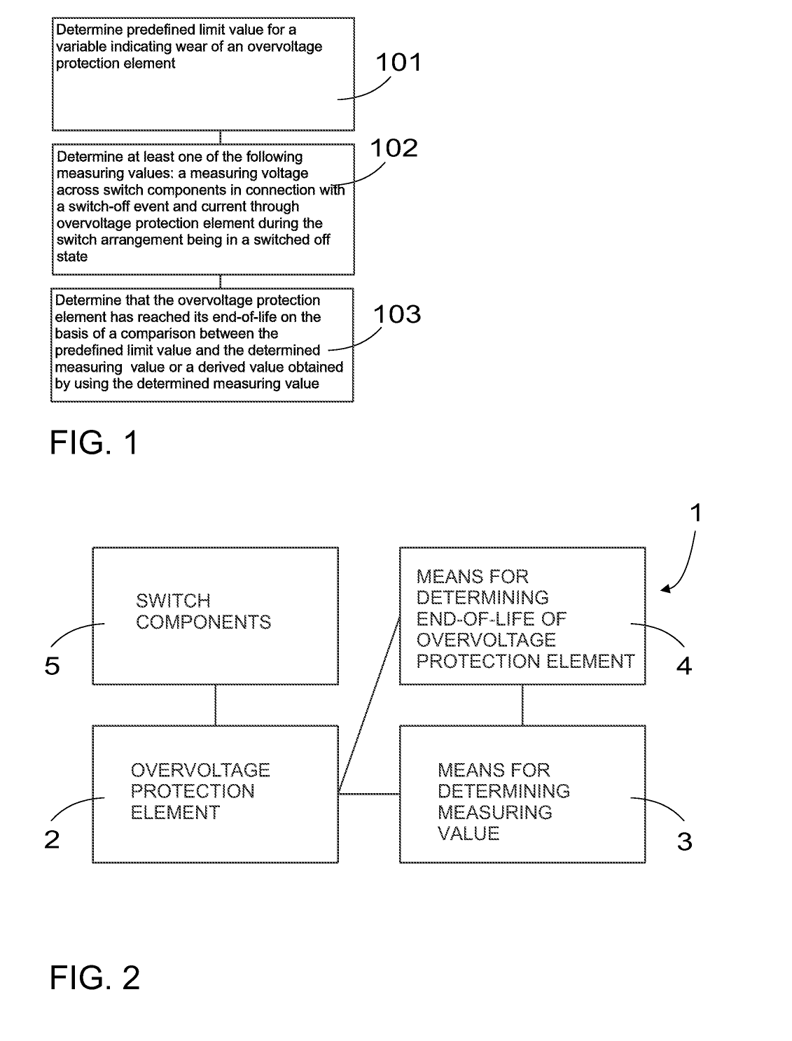

FIG. 1 describes schematically a method for determining an end-of-life of an overvoltage protection element in an electric circuit. Such a method may comprise determining 101 a predefined limit value for a variable indicating wear of an overvoltage protection element, determining 102 at least one of the following measuring values: a measuring voltage across switch components of the switch arrangement in connection with a switch-off event and current through the overvoltage protection element during the switch arrangement being in a switched off state, and determining 103 that the overvoltage protection element has reached its end-of-life on the basis of a comparison between the predefined limit value and the determined measuring value

According to an embodiment, the overvoltage protection element may have an original nominal voltage and the measuring value may comprise an actual measuring voltage. Such a method may comprise determining 101 a predefined voltage limit for the overvoltage protection element. This predefined voltage limit defines the degraded measuring voltage at which the overvoltage protection element is considered to have reached its end-of-life. According to an embodiment, the overvoltage protection element may comprise a varistor. This varistor may be a metal oxide varistor, for example.

According to an embodiment, the predefined voltage limit may be in the range of 85 to 92 percent of the nominal voltage of the overvoltage protection element. According to a further embodiment, the predefined voltage limit is approximately 90 percent of the nominal voltage of the overvoltage protection element.

According to an embodiment, the method may further comprise determining 102 a measuring voltage across switch components of the switch arrangement in connection with a switch-off event. The measuring voltage is the highest voltage detected across switch components and due to the characteristics of a varistor-type overvoltage protection element, this is the voltage at which the overvoltage protection element is in conductive state, The switch arrangement and the switch components may comprise different number and types of components and some embodiments related to them are explained in more detail further in this description. According to an embodiment, the overvoltage protection element may be connected in parallel to the switch components. According to an embodiment, the switch component may comprise two switches, such as a mechanical switch and a semi-conductor switch. These two switches may be connected in parallel to one another and to the overvoltage protection element.

A switch-off event may be an event of breaking the electric circuit in such a way that the current flow is blocked in the circuit or in a part thereof. As mentioned, overvoltage situations may occur, for instance, in connection of switching off inductive loads and the overvoltage protection elements are specifically designed to handle this kind of events and to help in avoiding damage to more sensitive components.

The method may further comprise determining 103 that the overvoltage protection element has reached its end-of-life when the measuring voltage is equal to or lower than the predefined voltage limit. In other words, an end-of-life of the overvoltage protection element is determined in response to the measuring voltage being equal to or lower than the predefined voltage limit. In other words, the determined measuring voltage across the switch components in connection with a switch-off event and the determined predefined voltage limit may be compared and if the measuring voltage is equal to or lower than the predefined voltage limit, the overvoltage protection element may be determined to have reached its end-of-life. According to an embodiment, the electric circuit may further comprise a control element and the measuring voltage across the switch components of the switch arrangement and end-of-life of the overvoltage protection element may be determined in the control element. According to an embodiment the control element may comprise a programmable integrated circuit (IC) like a field-programmable gate array (FPGA), a microcontroller (MCU) or a digital signal processor (DSP).

According to an embodiment, the electric circuit may further comprise means for measuring current in the electric circuit and memory means. Different types of means for measuring current and different types of memory means are known in the art and are therefore not explained in more detail. The predefined limit value may comprise a pre-estimated total energy value the overvoltage protection element is able to absorb over time. According to, an embodiment, the measuring value may comprise voltage and current measurements and/or the energy absorbed by the overvoltage protection element determined on the basis of these values. In other words, a derived value obtained by using the determined measuring value(s), such as voltage and current measurements, may be used in the comparison used for determining that the overvoltage protection element has reached its end-of-life. The method may then further comprise the steps of determining in the control element the energy absorbed by the overvoltage protection element on the basis of the voltage and current measurements and the duration of the pulse, storing in the memory means data about the energy absorbed by the overvoltage protection element over time, and comparing the energy absorbed by the overvoltage protection element over time and the pre-estimated total energy value and indicating, in response to the comparison, at least one of the following: an end-of-life of the overvoltage protection element and a relation between the overvoltage protection element over time and the pre-estimated total energy value. The principle of determining energy on the basis of voltage, current and the duration of the pulse is known as such and is therefore not explained in more detail. A benefit of this embodiment is that a manufacturer typically has already defined the pre-estimated total energy value the overvoltage protection element is able to absorb over time.

According to an embodiment, a graphical interface may be connected to the electric circuit and the method may further comprise indicating the end-of-life of the overvoltage protection element in the graphical user interface. In different embodiments, the graphical interface may be arranged in connection with the switch arrangement or it may comprise an external display, for example. In different embodiments, the graphical user interface may be arranged to indicate status information and/or measurements from the switch arrangement, such as at least one of the following: the end-of-life of the overvoltage protection element, the latest detected measuring voltage in connection with a switch-off event, the amount or ratio of degradation of the measuring voltage of the overvoltage protection element compared to the nominal voltage, the current through the overvoltage protection element during the switch being in a switched off state, the amount or increase in the current through the overvoltage protection element compared to the maximum allowed leakage current, and the amount of ratio of the energy absorbed by the overvoltage protection element over time compared to the pre-estimated total energy value the overvoltage protection element is able to absorb during its life cycle. According to a further embodiment, the user interface may also be configured to receive input from a user or operator, such as setting for and/or commands to the components of the switch arrangement.

According to an embodiment the method may further comprise indicating the end-of-life for a user In different embodiments, this may be realized by indicating the end-of-life on a graphical user interface, by a specific indicator, such as a visual and/or audible indicator, and/or by other means easily detected by a user. Similarly, according to an embodiment, a switch arrangement described below may be configured to indicate the end-of-life of the overvoltage protection element in such a way.

According to an embodiment, the method may further comprise precluding, in response to the determination of the end-of-life of the overvoltage protection element, the use of the switch arrangement until the overvoltage protection element has been replaced. Similarly, according to an embodiment, a switch arrangement described below may be configured to preclude the use of the switch arrangement until the overvoltage protection element has been replaced.

FIG. 2 is a schematic view of an arrangement for determining an end-of-life of an overvoltage protection element. Such a switch arrangement for switching an electric circuit may comprise switch components 5, an overvoltage protection element 2 having a predefined limit value for a variable indicating wear of an overvoltage protection element, means 3 for determining a measuring value, and means 4 for determining an end-of-life of the overvoltage protection element in response to the measuring voltage being equal or lower than the predefined voltage limit. The elements, components and concepts related to the arrangement are explained in more detail in connection with the method illustrated in the FIG. 1 and the related description.

According to an embodiment, the overvoltage protection element may comprise a varistor. The varistor may be a metal oxide varistor (MOV).

According to an embodiment, the predefined voltage limit may be in the range of 85 to 92 percent of the nominal voltage of the overvoltage protection element. According to a further embodiment, the predefined voltage limit is approximately 90 percent of the nominal voltage of the overvoltage protection element. In different embodiments, the predefined voltage limit range or value may depend on the leakage current values allowed for the switch/overvoltage protection element types in standards and/or an application in question.

According to an embodiment, the predefined limit value may comprise an allowed leakage current value, the measuring value may comprise the current through the overvoltage protection element during the switch being in a switched off state, and determining of the overvoltage protection element having reached its end-of-life may be done on the basis of the current through the overvoltage protection element during the switch being in a switched off state being equal or higher than the allowed leakage current. The allowed leakage current value may be based on a switch-specific limit value defined by standards or it may be defined separately for a circuit, an application, a specific purpose or to be otherwise suitable for the embodiment in question.

According to an embodiment, the electric circuit may further comprise a control element and the control element may be configured to determine the measuring value and end-of-life of the overvoltage protection element According to a further embodiment, the control element may comprise a programmable integrated circuit.

According an embodiment, a graphical interface may be connected to the electric circuit and the graphical interface may be configured to indicate the end-of-life of the overvoltage protection element in the graphical user interface.

FIG. 3 is a schematic view of an example of a switch arrangement for determining an end-of-life of an overvoltage protection element. Such a switch arrangement may be connected to an alternating current (AC) source or a direct current (DC) source 6. The switch arrangement may comprise switch components 5, which may comprise a main switch 5a and a secondary switch 5b connected between the source 6 and a load 7. According to an embodiment, the main switch 5a and the secondary switch 5b are connected in parallel between the source 6 and the load 7.

According to an embodiment, the main switch 5a may comprise a mechanical switch for switching off of the electric circuit. According to an embodiment, the mechanical switch may comprise a so called ultra-fast switch.

According to an embodiment, the secondary switch 5b may comprise a semiconductor switch. Preferably, the semiconductor switch is fully controllable such that it can be turned on and off at will. Such a semiconductor switch may comprise an insulated-gate bipolar transistor (IGBT), a gate turn-off thyristor (GTO) or an integrated gate-commutated thyristor (IGCT).

According to an embodiment, the switch arrangement may further comprise an overvoltage protection element 2. The overvoltage protection element 2 is preferably connected in parallel to the switch components. The overvoltage protection element 2 may be used to limit the voltage across the switches and absorbing the inductive energy of the main circuit in connection with overvoltage events, such as a switch-off event when breaking the current. The overvoltage protection element 2 may be a varistor, such as a metal oxide varistor, for example.

According to an embodiment, the switch arrangement may further comprise means 3 for determining a measuring voltage across the switch components in connection with a switch-off event, such as a voltage measurement unit 3a for measuring the measuring voltage and connected before and after the switch components 5, 5a, 5b of the main circuit as shown in Figure 3, for example. The wear and end-of-life may then be determined in a similar manner to at least one of those explained in connection with the other embodiments of the switch arrangement 1 and the method.

According to an embodiment, the switch arrangement may further comprise a graphical user interface 8. The graphical user interface may provide a user interface towards a user or operator. In different embodiment, different types of user interfaces may be used instead or in addition to a graphical user interface, as explained above. Examples of information that may be indicated on the user interface are also explained in more detail above.

According to an embodiment, the switch arrangement may further comprise a control element 4, such as a programmable integrated circuit 4a, like a field-programmable gate array (FPGA), a microcontroller (MCU) or a digital signal processor (DSP). In embodiments comprising a graphical or other type of a user interface as explained above, the user interface may be connected to the control element. According to a further embodiment, the user interface may also be configured to receive input, such as setting up settings for or providing commands to the components of the switch arrangement.

According to an embodiment, the switch arrangement may further comprise a current measurement unit 9 connected in the main circuit in series with the switch components 5, 5a, 5b. Current in the main circuit may be measured with current transducers, such as Closed Loop Hall Effect current transducers, or other suitable measurement components. Some benefits of current transducers comprise a good accuracy, wide frequency bandwidth and good galvanic isolation between primary and secondary. The secondary of the current measurement unit 9 may be connected to the control element 4, 4a and/or an overcurrent protection unit 10. The current measurement may be used for detecting an overcurrent event and for showing the current in the graphical user interface 8, for example.

According to an embodiment, the switch arrangement may, thus, further comprise an overcurrent protection unit 10. The overcurrent protection unit 10 may be connected to the current measurement unit 9 and to the control element 4, 4a and it may be configured to process the current measurement results to provide, for instance, an absolute value of the current and/or the absolute value of the rate of the current change. For instance, analog electronic circuits such as operation amplifiers may be used for may be used for producing the absolute value and the differentiator. The control element 4, 4a may then comprise an internal comparator, for example, for comparing the values provided to a reference value, which may, in different embodiments, be predefined or set from the graphical user interface 8, for example, and for detecting an overcurrent event in response to the provided value being above the reference value.

According to different embodiments, the switch arrangement may further comprise a first driving circuit 11 for the main switch 5a and/or a second driving circuit 12 for the secondary switch 5b. The control element 4 may be configured to generate control signals to the first driving circuit 11, which may be arranged to move the contacts, such as mechanical contacts, to an open or a closed position. The second driving circuit 12 may be connected between the control element 4 and the secondary switch 5b, such as a controllable semiconductor switch. The control element 4 may then be configured to generate control signals to the second driving circuit 12 for turning the switch, for instance the semiconductors, on or off. According to an embodiment, the driving circuits 11, 12 may comprise optocoupler drivers, for example. Some benefits of optocouplers comprise providing good voltage isolation between primary and secondary and a low propagation delay.

According to an embodiment, a switch, arrangement 1 described above may be used in a DC application. In such an embodiment, the absolute value circuits of the overcurrent protection unit 10 are usually not needed.

According to an embodiment, a switch arrangement 1 described above may be used in a 3-phase AC application. In such an application a main circuit and an overvoltage protection element 2 is preferably provided for each phase, thus multiplying the main circuit and the overvoltage protection elements by 3. In such an embodiment, circuits which detect the maximum of the absolute values of the phase currents and the maximum of the absolute values of the rate of the current changes may then be connected between overcurrent protection unit 10 and control element 4, 4a. According to another embodiment, a switch arrangement 1 described above may be used in a 1-phase AC application. In both 1-phase and 3-phase AC applications the voltage measurements may also be used for providing a zero voltage switch on and a zero current switch off, besides the determination of the overvoltage protection element end-of-life and/or wear.

In different embodiments of the method and the switch arrangement, the graphical user interface 8 may also comprise at least one of the following: waveform views of the phase voltage and currents, such as input voltage, load voltage and current in the main circuit, buttons or other means for switching the main switch on and off, settings for the overcurrent limits, overcurrent indicators if the value of the current and if the rate of the current change exceeds the limit value and on/off indicators of the switch. In some embodiments, also the frequency may be shown in user interface. The content, of the user interface may vary depending on the type of application it is designed for or a standard user interface may be adaptable for different applications.

In embodiments such as those described in connection with FIG. 3, in an overcurrent event after detecting an overcurrent event the control element 4, 4a may generates a turn on signal to the secondary switch and open signal to main switch to commutate the current to the secondary switch. After a predefined time, when the air cap between the contacts of the main switch is sufficient, the control element may then generate a turn off signal to the secondary switch to break the current in the main circuit. The sufficient air cap is when the breakdown voltage of the air cap is bigger than the protection level of the overvoltage protection element connected in parallel to the switch components 5, 5a, 5b. After turning off the secondary switch the voltage over the switch components starts to increase because of the inductance in the main circuit. When the voltage is over a predefined protection level, the overvoltage protection element forms a low resistance shunt across the switch components 5, 5a, 5b. The energy stored in the inductances of the main circuit is then absorbed in the overvoltage protection element 2.

In different embodiments, a combination of the different predefined limit values or derived values obtained by using, them and/or the different measuring values described in this description may be used for determining that an overvoltage protection element has reached its end-of-life. A suitable combination of values and/or measurement can be selected based on the application, accuracy requirements, a multifunctional use of components and/or on other such basis.

It will be obvious to a person skilled in the art that, as the technology advances, the inventive concept can be implemented in various ways. The invention and its embodiments are not limited to the examples described above but may vary within the scope of the claims.

1. A method for determining an end-of-life of an overvoltage protection element of a switch arrangement in an electric circuit, wherein the method comprises:
determining a predefined limit value for a variable indicating wear of an overvoltage protection element,
determining at least one of the following measuring values: a measuring voltage across switch components of the switch arrangement in connection with a switch-off event and current through the overvoltage protection element during the switch arrangement being in a switched off state, and
determining that the overvoltage protection element has reached its end-of-life on the basis of a comparison between the predefined limit value and the determined measuring value or a derived value obtained by using the determined measuring value.

2. A method according to claim 1, wherein the overvoltage protection element has a nominal voltage, wherein the method comprises:
determining a predefined voltage limit based on the nominal voltage for the overvoltage protection element,
determining a measuring voltage across switch components of the switch arrangement in connection with a switch-off event, and
determining that the overvoltage protection element has reached its end-of-life when the measuring voltage is equal to or lower than the predefined voltage limit.

3. A method according to claim 2, wherein the overvoltage protection element comprises a varistor.

4. A method according to claim 2 or 3, wherein the predefined voltage limit is in the range of 85 to 92 percent of the nominal voltage of the overvoltage protection element.

5. A method according to claim 4, wherein the predefined voltage limit is approximately 90 percent of the nominal voltage of the overvoltage protection element.

6. A method according to any one of claims 1 to 5, wherein the electric circuit further comprises a control element and wherein the measuring value and end-of-life of the overvoltage protection element are determined in the control element.

7. A method according to claim 6, wherein the control element comprises a programmable integrated circuit.

8. A method according to any one of claims 1 to 7, wherein a graphical interface is connected to the electric circuit and the method further comprises indicating the end-of-life of the overvoltage protection element in the graphical user interface.

9. A method according to any one of claims 6 to 8, wherein the electric circuit further comprises means for measuring current in the electric circuit and memory means, wherein the predefined limit value comprises a pre-estimated total energy value the overvoltage protection element is able to absorb over time, and wherein the method further comprises
determining in the control element the energy absorbed by the overvoltage protection element on the basis of the voltage and current measurements and the pulse duration,
storing in the memory means data about the energy absorbed by the overvoltage protection element over time, and
comparing the energy absorbed by the overvoltage protection element over time and the pre-estimated total energy value and indicating, in response to the comparison, at least one of the following: an end-of-life of the overvoltage protection element and a relation between the determined energy absorbed by the overvoltage protection element over time and the pre-estimated total energy value.

10. A method according to any one of claims 1 to 9, wherein
the predefined limit value comprises an allowed leakage current value, the measuring value comprises the current through the overvoltage protection element during the switch arrangement being in a switched off state, and wherein
determining that the overvoltage protection element has reached its end-of-life is done on the basis of the current through the overvoltage protection element during the switch arrangement being in a switched off state being equal or higher than the allowed leakage current.

11. A switch arrangement for switching an electric circuit comprising:
switch components,
overvoltage protection element having a predefined limit value for a variable indicating wear of an overvoltage protection element,
means for determining at least one of the following measuring values: a measuring voltage across switch components of the switch arrangement in connection with a switch-off event and current through the overvoltage protection element during the switch arrangement being in a switched off state, and
means for determining an end-of-life of the overvoltage protection element in response to a comparison between the predefined limit value and the determined measuring value or a derived value obtained by using the determined measuring value.

12. A switch arrangement according to claim 11, wherein the overvoltage protection element comprises a varistor.

13. A switch arrangement according to claim 11 or 12, wherein the predefined limit value comprises a predefined voltage limit and the predefined voltage limit is in the range of 85 to 92 percent of a nominal voltage of the overvoltage protection element.

14. A switch arrangement according to claim 13, wherein the predefined voltage limit is approximately 90 percent of the nominal voltage of the overvoltage protection element.

15. A switch arrangement according to any one of claims 11 to 14, wherein the electric circuit further comprises a control element and wherein the control element is configured to determine the measuring value and the end-of-life of the overvoltage protection element.

16. A switch arrangement according to claim 15, wherein the control element comprises a programmable integrated circuit.

17. A switch arrangement according to any one of claims 11 to 16, wherein a graphical interface is connected to the electric circuit and the graphical interface is configured to indicate the end-of-life of the overvoltage protection element in the graphical user interface.
